(19) United States
(12) Patent Application Publication
(10) Pub. No.: US 2020/0067284 A1
(43) Pub. Date: Feb. 27, 2020

(54) Specialized In-Wall Mounting Apparatus for Vertically and Inversely-Orienting a Virtualized Hardware Box

(71) Applicant: EWIRED SOLUTIONS, INC., Morgan Hill, CA (US)

(72) Inventors: Steven Joseph Dudek, Morgan Hill, CA (US); Moses Pedro Sanchez, Morgan Hill, CA (US)

(73) Assignee: EWIRED SOLUTIONS, INC.

(21) Appl. No.: 16/550,213

(22) Filed: Aug. 24, 2019

Related U.S. Application Data
(60) Provisional application No. 62/722,821, filed on Aug. 24, 2018.

(51) Int. Cl. H02B 1/44; H02B 1/56; H02B 1/42; H05K 7/14; H02G 3/36; E06B 9/52

(52) U.S. Cl. CPC H02B 1/44; H02B 1/56; H02B 1/42; E06B 2009/527; H02G 3/36; E06B 9/52; H05K 7/1497

(57) ABSTRACT

A specialized in-wall mounting apparatus encapsulates a virtualized hardware box and related electronic components in a uniquely-vertical and inverse orientation. The specialized in-wall mounting apparatus holds the virtualized hardware box vertically and inversely (i.e. upside down) with mounting brackets to position the front plate of the virtualized hardware box to face the ground, the rear plate to face up, and the body of the virtualized hardware box to be parallel to a vertical wall. Preferably, the specialized in-wall mounting apparatus is partially embedded in the vertical wall, with a carved-in section on the vertical wall. The apparatus may also optionally incorporate a thermal dissipation meshed screen front door. Furthermore, instead of utilizing a conventional MDF room, multiple specialized in-wall mounting apparatuses may be embedded in multiple office rooms in a distributed manner to connect multiple virtualized hardware boxes and PoE switches through in-wall distributed Ethernet cabling and fiber backbone.

### BACKGROUND OF THE INVENTION

The present invention generally relates to electronic device mounting racks and enclosures. More specifically, the present invention relates to a specialized in-wall mounting apparatus that vertically and inversely orients and holds a virtualized hardware box in an in-wall closet enclosure. Additionally, the present invention also relates to integrating a novel thermal dissipation door to the in-wall closet enclosure.

Furthermore, the present invention also relates to accommodating novel depth-axis-stackable (i.e. z-axis-stackable) installation of virtualized hardware boxes or other electronic equipment. Moreover, the present invention also relates to enabling distributed in-wall configurations of a plurality of virtualized hardware boxes in a multiple office room environment that replaces a conventional main distribution frame (MDF) room or another centralized MDF location for the multiple office room environment.

Conventional information technology (IT) management in a professional office environment typically involves a centralized location, such as an MDF room, for data signal distribution to a variety of local data access points in various rooms or floors. For example, as shown in FIG. 1, a typical MDF room contains one or more computer server racks that horizontally stack up numerous computer servers to process, route, and/or distribute electronic signals to a plurality of office rooms or floors through wired cables connected to more localized data access points. Computer servers horizontally stacked up in multiple server racks in an MDF room create significant challenges in cable connection management and maintenance, as the number of cable connections grow exponentially and become highly complicated for each computer server added to a server rack.

As shown in FIG. 2, cable connections that link various hardware and server components in an MDF room are often too complex to trace and maintain rapidly or conveniently. For example, an accidentally-tripped wire by a janitor or an IT technician in the MDF room can cause an elusive data network outage that may require time-consuming and manual cable connection checking and tracings in the MDF room for troubleshooting, while the overall productivity in the office space is reduced during the data network downtime. Furthermore, as also illustrated by FIG. 1 and FIG. 2, conventional horizontally-stacked server racks take up exorbitant amount of extra space beyond the size of each rack itself for data cable and power cable connections, while also necessitating cable ladders and seismic protection braces around the horizontally-stacked sever racks in the MDF room.

Therefore, it may be desirable to devise a novel apparatus configured to orient, mount, and encapsulate electronic devices in clever dimensions to reduce cable connection complexities and extra space requirements, which are often necessitated in a conventional horizontally-stackable server rack.

Furthermore, it may also be desirable to devise the novel apparatus that orient, mount, and encapsulate the electronic devices with a thermally-efficient door that removes heat generated by the encapsulated electronic devices efficiently, even when the door is fully closed.

In addition, it may also be desirable to devise a decentralized and/or distributed in-wall configurations of a plurality of virtualized hardware boxes in a multiple office room environment in lieu of a conventional main distribution frame (MDF) room for ease of installation, maintenance, and space efficiencies.

### SUMMARY

Summary and Abstract summarize some aspects of the present invention. Simplifications or omissions may have been made to avoid obscuring the purpose of the Summary or the Abstract. These simplifications or omissions are not intended to limit the scope of the present invention.

In a preferred embodiment of the invention, a specialized in-wall mounting apparatus is disclosed. This apparatus comprises: a main body frame configured to vertically and inversely orient and hold a virtualized hardware box inside the specialized in-wall mounting apparatus with one or more brackets, wherein a front plate of the virtualized hardware box faces down to be parallel to a floor and a rear plate of the virtualized hardware box faces up to keep a bottom surface and a top surface of the virtualized hardware box parallel to a vertical wall that attached the main body frame of the specialized in-wall mounting apparatus; and an in-wall mount apparatus doorframe configured to open or close an enclosure space provided by the main body frame, wherein the in-wall mount apparatus doorframe opens outward from the vertical wall that attached the main body frame of the specialized in-wall mounting apparatus.

### BRIEF DESCRIPTION OF DRAWINGS

FIG. 1 shows a conventional horizontally-stackable computer server rack mount with cable ladders and seismic protection frames that require an inordinate amount of space beyond actual dimensions of conventional server racks.

FIG. 2 shows typical cable management complications in a conventional horizontally-stackable computer server rack mount.

FIG. 3 shows a closed-door screenshot of a specialized in-wall mounting apparatus that vertically and inversely orients a virtualized hardware box, in accordance with an embodiment of the invention.

FIG. 4 shows an open-door screenshot of a specialized in-wall mounting apparatus that vertically and inversely orients a virtualized hardware box, in accordance with an embodiment of the invention.

FIG. 5 shows a closed-door screenshot of a specialized in-wall mounting apparatus incorporating a thermal dissipation meshed screen front door that vertically and inversely orients a virtualized hardware box, in accordance with an embodiment of the invention.

FIG. 6 shows an open-door screenshot of a specialized in-wall mounting apparatus incorporating a thermal dissipation meshed screen front door that vertically and inversely orients a virtualized hardware box, in accordance with an embodiment of the invention.

FIG. 7 shows a distributed in-wall system configuration for data and communication management in replacement of a conventional centralized MDF room, in accordance with an embodiment of the invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

The detailed description is presented largely in terms of descriptions of shapes, configurations, and/or other symbolic representations that directly or indirectly resemble one or more specialized in-wall mounting apparatuses for vertically and inversely-orienting a virtualized hardware box or another computer server component. These descriptions and representations are the means used by those experienced or skilled in the art to most effectively convey the substance of their work to others skilled in the art.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment. Furthermore, separate or alternative embodiments are not necessarily mutually exclusive of other embodiments. Moreover, the order of blocks in process flowcharts or diagrams representing one or more embodiments of the invention does not inherently indicate any particular order nor imply any limitations in the invention.

For the purpose of describing the invention, a term herein referred to as “vertically and inversely-orienting” is defined as placing a bottom surface and/or a top surface of a computer server case or another hardware component case parallel to a vertical wall (i.e. vertical orientation), while also positioning a front plate of the computer server case or another hardware component in a face-downward position (i.e. inverse orientation) to make the front plate parallel to the floor. For example, a specialized in-wall mounting apparatus designed to “vertically and inversely orient” a virtualized hardware box, in accordance with an embodiment of the present invention, places and securely holds the virtualized hardware box's bottom surface and top surface to be parallel to a vertical wall attached to the specialized in-wall mounting apparatus, while positioning the virtualized hardware box's front plate to face downward and parallel to the floor.

Moreover, for the purpose of describing the invention, a term herein referred to as “in-wall” is defined as being attached to or being embedded into a vertical wall of an office room or another building structure. For example, a specialized in-wall mounting apparatus for a virtualized hardware box, in context of various embodiments of the present invention, is configured to dock into a recessed portion of the vertical wall, wherein the recessed portion is specifically carved into the vertical wall to provide a flush fitting and at least partial embedding of the exterior casing of the specialized in-wall mounting apparatus. The carved and recessed portion of the vertical wall may also provide inner wall-embedded electrical and/or optical cable connections between the virtualized hardware box mounted inside the specialized in-wall mounting apparatus and other electronic devices in the vicinity, without exposing cable connection clutters outside the vertical wall.

In addition, for the purpose of describing the invention, a term herein referred to as “virtualized hardware box” is defined as a miniaturized and combined computer server that executes one or more advanced hardware virtualization software to provide multiple functionalities of multiple number of discrete computer servers and other communication hardware components within one physical computing server casing. For example, a corporate email server, a corporate web server, a cloud storage server, and/or another computing hardware component that operate in separate computing servers in a conventional IT configuration may be integrated into one virtualized hardware box that utilizes a suite of advanced hardware virtualization software to provide various functionalities of historically-separate and discrete computing servers via software-based hardware functionality virtualizations and emulations. In many instances, virtualized hardware boxes can reduce the number of unnecessary computer servers, server room space inefficiencies, IT operating costs, and IT server room implementation or upgrade complexities via flexible software-level multiple hardware functional emulations in dynamically changing needs of a corporate IT department.

Moreover, for the purpose of describing the invention, a term herein referred to as “depth-axis” or “z-axis” is defined as a dimension of thickness perpendicular to a vertical wall. In context of various embodiments of the present invention, the depth-axis or z-axis is correlated to the thickness (i.e. as opposed to a horizontal length (x-axis) or a height (y-axis)) of a specialized in-wall mounting apparatus, which may have a thick or thin depth dimension “into the wall” or “out of the wall,” when the apparatus is mounted into the vertical wall. Therefore, a depth-axis or z-axis stackable installation of virtualized hardware boxes refer to the specialized in-wall mounting apparatus' unique capability to stack multiple hardware boxes “into the wall” or “out of the wall” along the wall's depth axis, which is perpendicular to the wall, while also uniquely providing vertical and inverse orientations to each stacked device encapsulated in the specialized in-wall mounting apparatus.

Furthermore, for the purpose of describing the invention, a term herein referred to as a “module” is defined as a specialized logical component comprising one or more software and/or chip-encoded hardware logical units that perform special-purpose task(s) and function(s) provided by an in-wall mounting apparatus or by a virtualized hardware box securely mounted inside the mounting apparatus.

One aspect of an embodiment of the present invention is providing a novel in-wall mounting apparatus that vertically and inversely orients, holds, and/or encapsulates a virtualized hardware box inside the in-wall mounting apparatus.

Another aspect of an embodiment of the present invention is providing and integrating a novel thermal dissipation door to the in-wall mounting apparatus.

Yet another aspect of an embodiment of the present invention is providing a novel depth-axis-stackable (i.e. z-axis-stackable) installation of virtualized hardware boxes or other electronic equipment.

Furthermore, another aspect of an embodiment of the present invention is providing distributed in-wall configurations of a plurality of virtualized hardware boxes in a multiple office room environment that replaces a conventional main distribution frame (MDF) room or another centralized MDF location for the multiple office room environment.

In addition, another aspect of an embodiment of the present invention is providing a novel in-wall mounting apparatus that can be utilized in implementing a novel distributed in-wall configuration of multiple virtualized hardware boxes in a multiple office room environment to reduce IT equipment footprints in a space-constrained office environment, cable entanglements, misconnections, disconnections, and related troubleshooting needs.

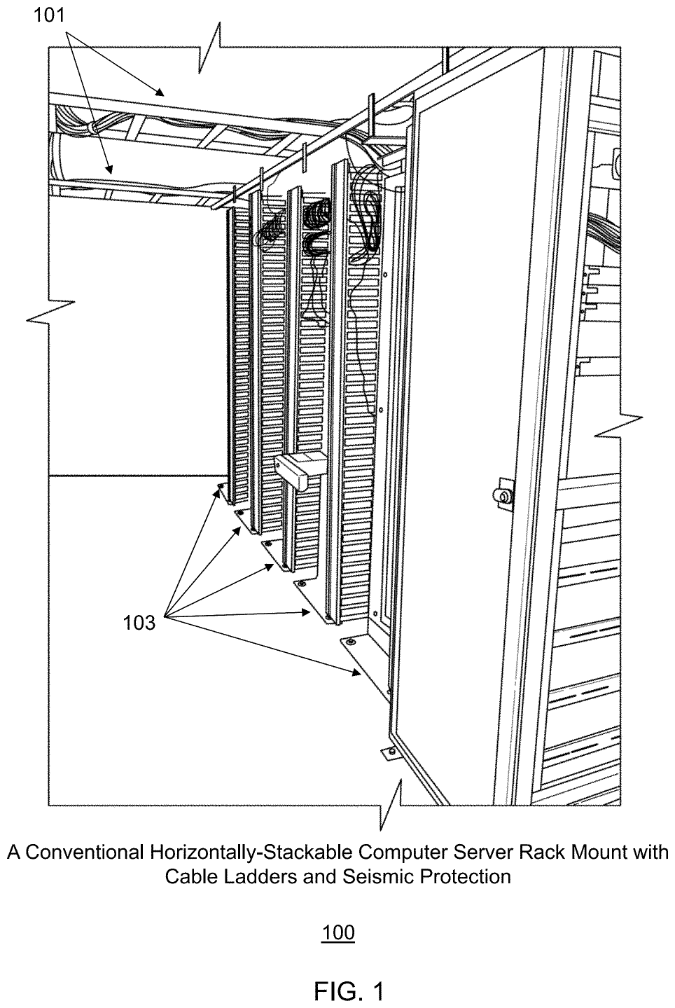

FIG. 1 shows an example (100) of conventional horizontally-stackable computer server rack mounts with cable ladders (101) and seismic protection frames (103) that require an inordinate amount of space beyond actual dimensions of conventional server racks. Typically, the horizontal stacking of computer servers requires an office floor footprint substantially larger than the accumulative dimensions of server racks operationally deployed in the vicinity, because of extra space requirements associated with computer server cable connections, cable ladders, and seismic protection frames, as illustrated by the example (100) in FIG. 1.

Therefore, conventional horizontally-stackable computer server rack mounts are not suitable for localized or distributed placements in various office rooms, and are instead typically placed in a discrete IT backroom (i.e. an MDF room) in an office environment, where data signal distribution originates for controlled distribution to a variety of local data access points in various rooms or floors in the office environment. For example, as shown in FIG. 1, a typical MDF room contains one or more computer server racks that horizontally stack up numerous computer servers to process, route, and/or distribute electronic signals to a plurality of office rooms or floors through wired cables connected to more localized data access points. Importantly, computer servers horizontally stacked up in multiple server racks in an MDF room create significant challenges in cable connection management and maintenance, as the number of cable connections grow exponentially and become highly complicated for each computer server added to a server rack.

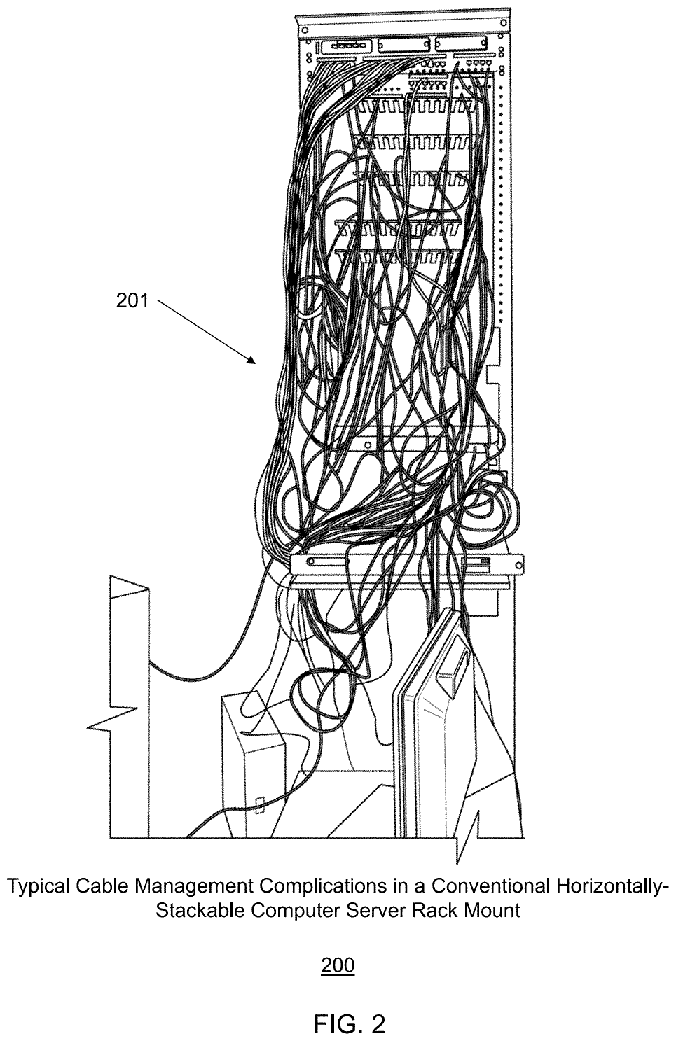

FIG. 2 shows typical cable management complications (200) in a conventional horizontally-stackable computer server rack mount positioned in an MDF room. As shown in FIG. 2, cable connections that link various hardware and server components in the MDF room are often too complex to trace and maintain rapidly or conveniently. For example, an accidentally-tripped wire by a janitor or an IT technician in the MDF room can cause a seemingly-mysterious and difficult-to-identify data network outage that may require arduous and extensive cable connection checking and tracings in the MDF room for troubleshooting, while the overall productivity in the office space is reduced during the data network downtime.

Server cable connection and MDF room management have traditionally been a significant challenge for IT installation and maintenance professionals, who are often forced to come up with compromises or undesirable temporary solutions to resolve MDF room space constraints and strenuous troubleshooting due to the complexity of wiring and cable connections (e.g. 201) in MDF rooms, as illustrated by the typical cable management complications (200) in FIG. 2. Furthermore, the complexities associated with MDF room-based centralized IT installations, extra office space requirements, and cable connection troubleshooting challenges also keep the cost of IT installations and maintenances unnecessarily high due to their space and labor-intensive tendencies in typical corporate IT operational environments.

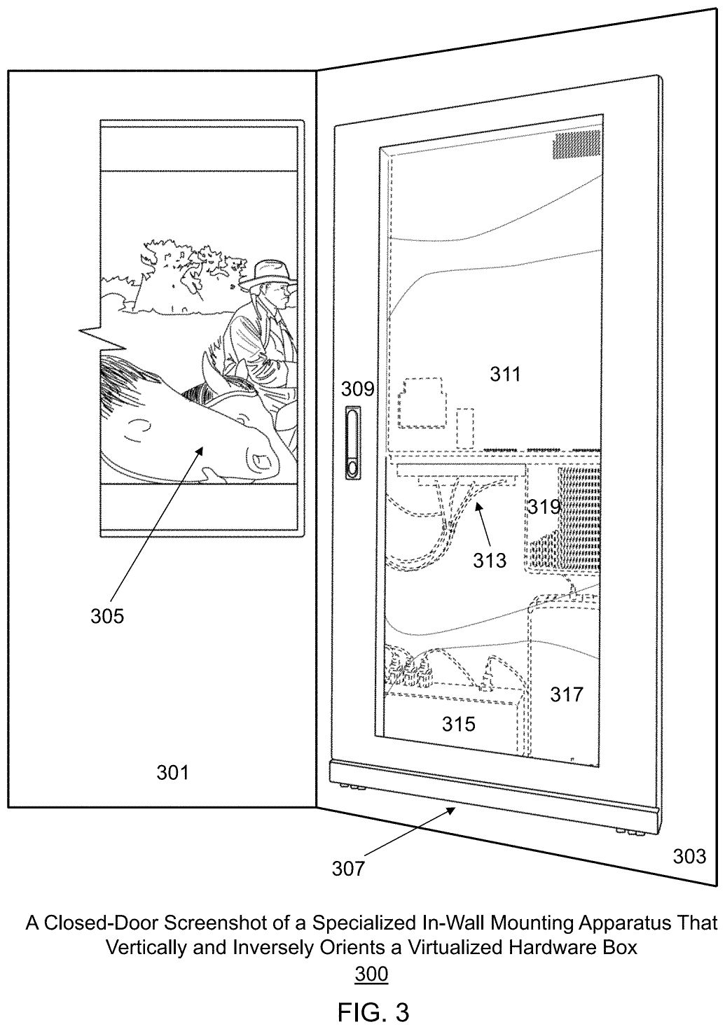

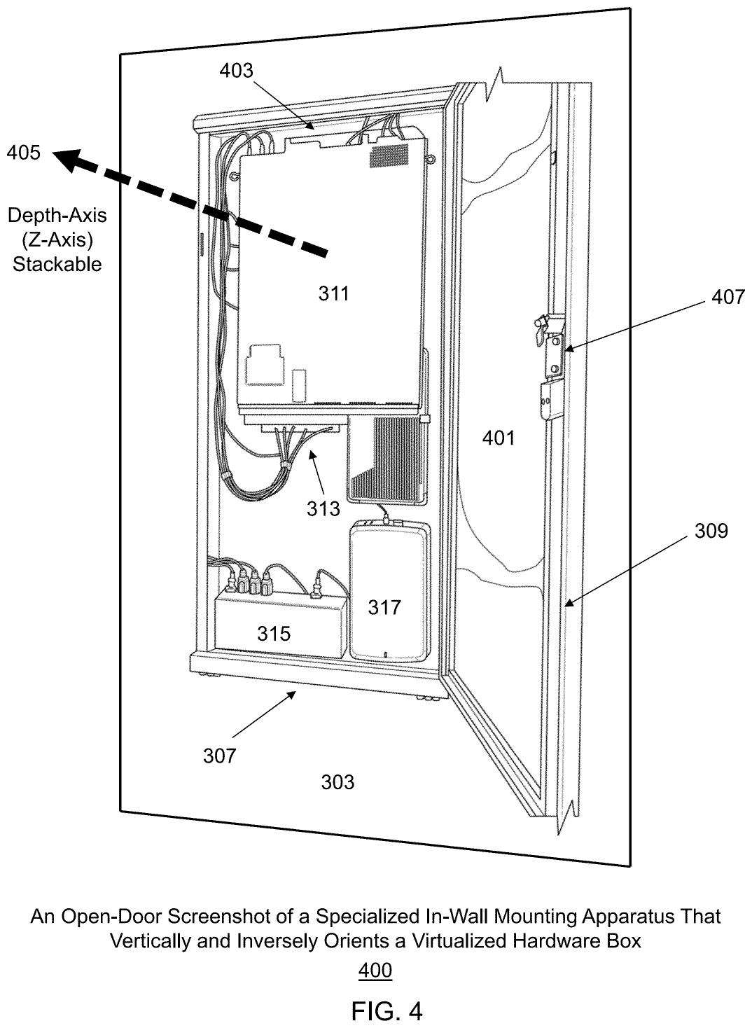

FIG. 3 shows a closed-door screenshot (300) of a specialized in-wall mounting apparatus with a main body frame (307) that vertically and inversely orients a virtualized hardware box (311), in accordance with an embodiment of the invention. The main body frame (307) of the specialized in-wall mounting apparatus in this embodiment of the invention encapsulates and securely holds the virtualized hardware box (311) by placing the bottom surface and the top surface of the virtualized hardware box (311) in vertical orientation and parallel to a vertical wall (303), while also positioning the front plate (313) of the virtualized hardware box (313) in a face-down orientation to make the front plate (313) parallel to the floor, as shown in FIG. 3. In this vertically and inversely-oriented device mount configuration, the rear plate (e.g. 403 in FIG. 4) of the virtualized hardware box is positioned in a face-up orientation to enable seamless backend power cable connections that can be hidden inside or behind the vertical wall, while the face-down front plate enables easier maintenance in a swing-up position and convenient data cable connections to local data access points (317) or Power-over-Ethernet (PoE) devices (319). The main body frame (307) of the specialized in-wall mounting apparatus may also encapsulate a power supply unit (315) inside its enclosure, thus further reducing cable and cord clutters and improving space efficiency and aesthetic appeals of this novel in-wall mounting apparatus.

Importantly, the specialized and novel in-wall mounting apparatus, as shown in FIGS. 3-6, provides significant space savings, improved aesthetic appeals, and simpler cable connections and maintenance, compared to conventional horizontally-stackable computer server rack mounts with cable ladders and seismic protection frames that require extra spaces beyond actual dimensions of conventional server racks. As shown in FIG. 3, for example, the specialized in-wall mounting apparatus can be positioned adjacent to another vertical wall (301) that mounts a hangable ornament or a wall-mountable electronic device, such as a display panel (305). The space savings and the improved aesthetic appeals enabled by the specialized and novel in-wall mounting apparatus, compared to conventional server rack mounts previously demonstrated in FIGS. 1-2, are evident in the closed-door screenshot (300) of the specialized in-wall mounting apparatus in FIG. 3.

Moreover, in a preferred embodiment of the invention, the specialized in-wall mounting apparatus (307) can be at least partially embedded into a vertical wall (e.g. 303 in FIGS. 3-4) of an office room or another building structure. As illustrated in FIGS. 3-6, the main body frame (307) of the specialized in-wall mounting apparatus is configured to dock into a recessed portion of the vertical wall (303), wherein the recessed portion is specifically carved into the vertical wall to provide a flush fitting and at least partial embedding of the exterior casing of the specialized in-wall mounting apparatus. In the preferred embodiment of the invention, the carved and recessed portion of the vertical wall (303) may also provide inner wall-embedded electrical and/or optical cable connections between the virtualized hardware box (311) mounted inside the main body frame (307) of the specialized in-wall mounting apparatus and other electronic devices (e.g. 315, 317, 319) in the vicinity, without exposing cable connection clutters outside the vertical wall (303).

Furthermore, the main body frame (307) of the specialized in-wall mounting apparatus, as illustrated in FIG. 4, is uniquely configured to stack a multiple number of virtualized hardware boxes along the “depth-axis,” (405) which is also known as the z-axis. The depth-axis/z-axis (405), in context of various embodiments of the present invention, is a dimension of thickness perpendicular to a vertical wall (e.g. 303), which is correlated to the thickness (i.e. as opposed to a horizontal length (x-axis) or a height (y-axis)) of a specialized in-wall mounting apparatus. The z-axis depth dimension “into the wall” or “out of the wall,” when the apparatus is mounted into the vertical wall, controls the number of virtualized hardware boxes that can be stacked along the z-axis/depth-axis (405). The depth-axis “stackability” of virtualized hardware boxes that are vertically and inversely (i.e. the front plate of the virtualized hardware box facing down) oriented within the main body frame (307) of the specialized in-wall mounting apparatus provides novel space saving optimizations by eliminating the need for physical standalone server rack footprints, cable ladders, backend cable connection spaces, and seismic protection frames, which are typically required in conventional server racks to position conventional horizontally-stacked computing devices in an MDF room.

FIG. 4 shows an open-door screenshot (400) of the specialized in-wall mounting apparatus that vertically and inversely orients a virtualized hardware box (e.g. 311), in accordance with an embodiment of the invention. In a preferred embodiment of the invention, the main body frame (307) of the specialized in-wall mounting apparatus is able to mount and encapsulate a vertically and inversely-oriented virtualized hardware box (e.g. 311), a data router unit (e.g. 317), a network firewall, a Power-over-Ethernet (PoE) network switch (e.g. 319), and an uninterruptible power supply (UPS) with an integrated battery (e.g. 315), with one or more mounting brackets contained inside the main body frame (307), as shown by the open-door screenshot (400) in FIG. 4. In one example, the specialized in-wall mounting apparatus is docked and at least partially embedded into the vertical wall (303), and is sufficiently large enough to mount and encapsulate these hardware components inside the apparatus.

Furthermore, in one embodiment of the invention, the specialized in-wall mounting apparatus is configured to encapsulate one or more virtualized hardware boxes (e.g. 311) by stacking them along the depth-axis (i.e. z-axis) (405) and utilizing depth-axis braces or depth-axis mounting brackets to securely hold the stacked virtualized hardware boxes together. The novel “stackability” of vertically and inversely-oriented virtualized hardware boxes along the depth-axis (i.e. z-axis) in the specialized in-wall mounting apparatus provides significant space savings advantages, compared to conventional horizontally-stacked computing devices positioned on conventional server racks in an MDF room, by eliminating the need for physical standalone server rack footprints, cable ladders, backend cable connection spaces, and seismic protection frames.

Moreover, the specialized in-wall mounting apparatus may also incorporate an in-wall mount apparatus doorframe (309) to access the vertically and inversely-oriented virtualized hardware box (e.g. 311), a PoE device (e.g. 319), a router (e.g. 317), and/or a power supply unit (e.g. 315) for maintenance, repair, or reinstallation. The in-wall mount apparatus doorframe (309) may further include a door latch (407) and a glass or plastic window (401) surrounded by the doorframe in this particular embodiment, as shown in FIG. 4. In another embodiment of the invention, the in-wall mount apparatus doorframe (309) may support a thermally more efficient material other than a conventional glass or a transparent/translucent plastic window (e.g. 401) for an improved thermal dissipation via frontal passive cooling from the in-wall mounting apparatus.

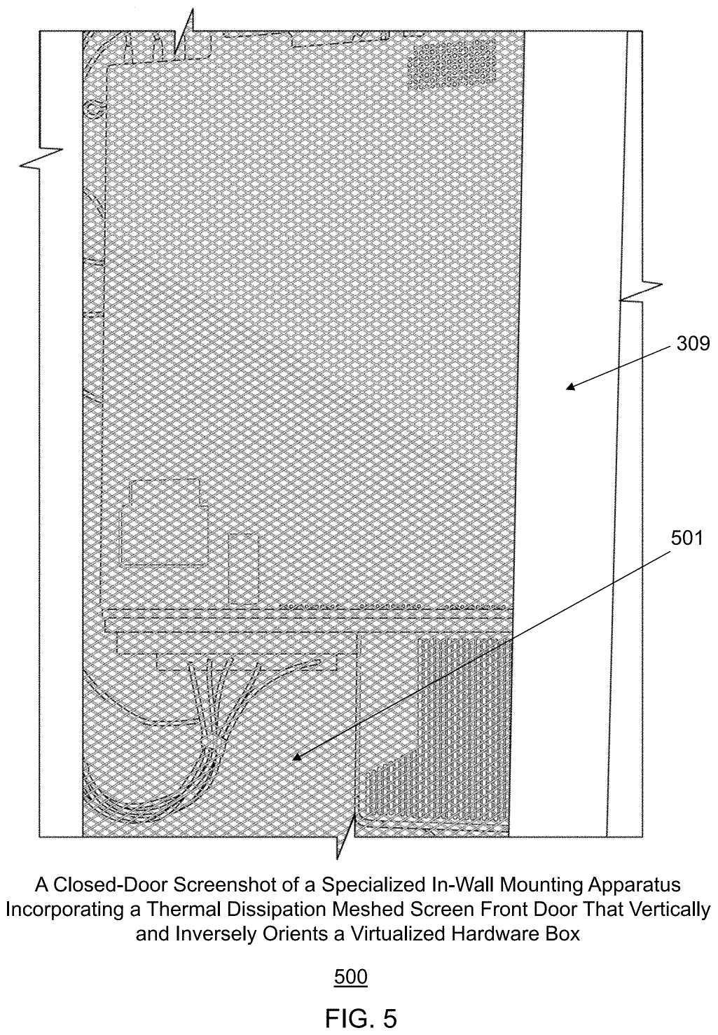

FIG. 5 shows a closed-door screenshot (500) of a specialized in-wall mounting apparatus incorporating a thermal dissipation meshed screen front door (501) supported by the in-wall mount apparatus doorframe (309), wherein the specialized in-wall mounting apparatus vertically and inversely orients a virtualized hardware box, in accordance with an embodiment of the invention. In one instance, the meshed screen utilized for the thermal dissipation meshed screen front door (501) may be made of thin metallic, plastic, rubber, or composite wires. In another instance, the meshed screen utilized for the thermal dissipation meshed screen front door (501) may be made of metallic, natural, polyester, or other synthetic strings. Preferably, the size of each hole created by the meshed screens is large enough to provide effective frontal thermal dissipation, and small enough to contain all cords, cables, and clutter inside the specialized in-wall mounting apparatus, as illustrated by the closed-door screenshot (500) in FIG. 5.

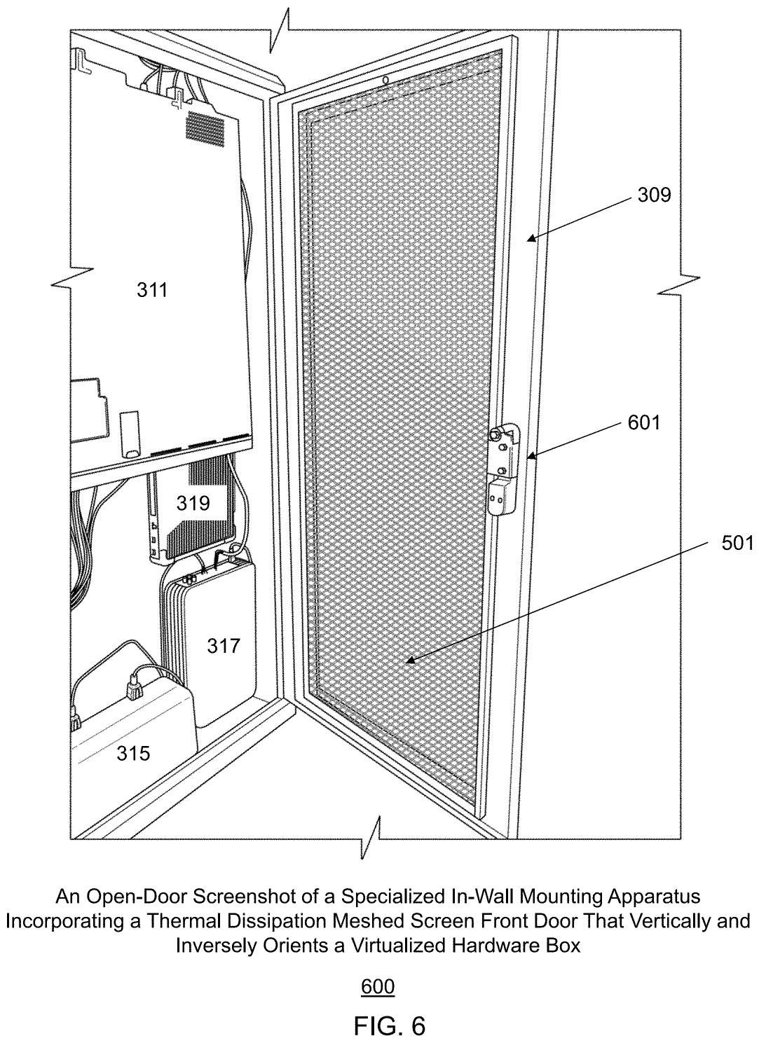

Similarly, FIG. 6 shows an open-door screenshot (600) of the specialized in-wall mounting apparatus incorporating the thermal dissipation meshed screen front door (501) supported by the in-wall mount apparatus doorframe (309). The thermal dissipation meshed screen front door (501) in this example also incorporates a door latch and a door lock element (601) to provide a flush closure of the door and a desirable level of security to deter theft or vandalism of the vertically and inversely oriented virtualized hardware box (311) and other electronic components (315, 317, 319) also contained inside the apparatus, such as wireless routers, Power-over-Ethernet (PoE) devices, and a fail-safe power supply.

As shown by FIGS. 5-6, the thermal dissipation meshed screen front door (501) enables efficient and passive heat removal from one or more depth axis-stacked (e.g. 405 in FIG. 4) virtualized hardware boxes and other electronic components, while maintaining clutter-free aesthetics in an office room environment. Furthermore, in some embodiments of the invention, the thermal dissipation meshed screen also eliminates the need for an active fan-based cooling unit inside the in-wall mounting apparatus, thus reducing ambient noise levels and power consumption for each installed in-wall mounting apparatus in the office room environment.

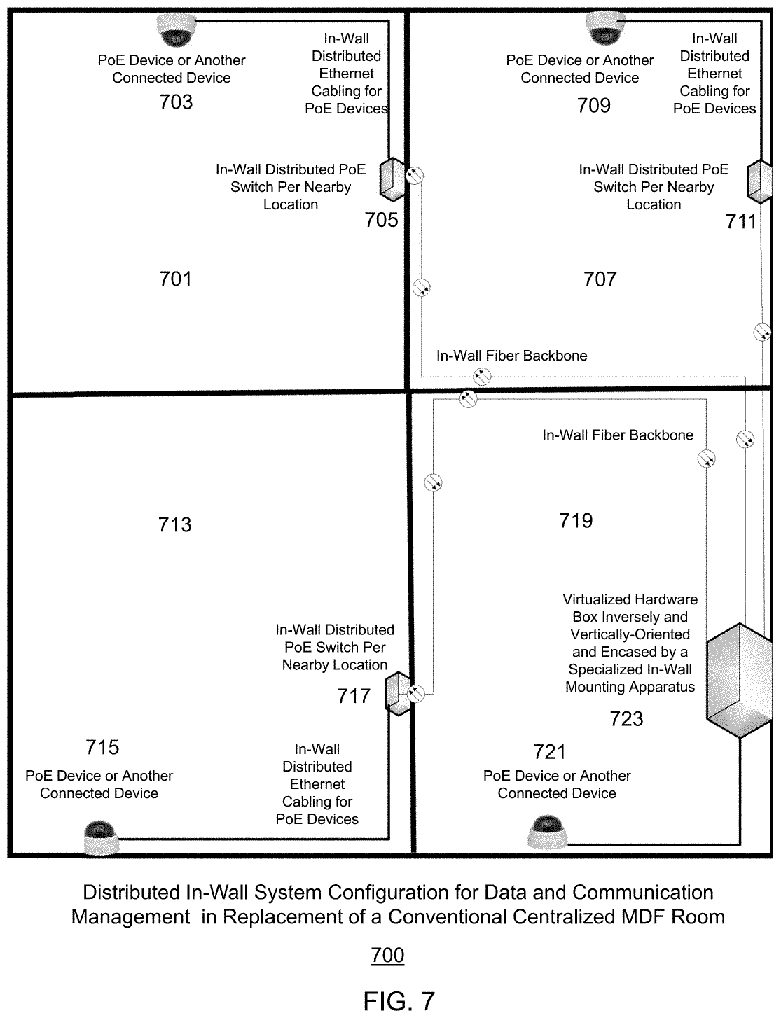

FIG. 7 shows a novel distributed in-wall system configuration (700) for data and communication management in replacement of a conventional centralized MDF room, in accordance with an embodiment of the invention. In conventional corporate IT implementations, a horizontally-stackable server rack is generally unsuitable and impractical for distributed in-room network and data equipment allocations due to extra space requirements necessitated by a cable ladder, a seismic protection frame, server rack floor footprints, as previously illustrated in FIGS. 1-2. Exposed cable connections near the horizontally-stackable server rack are also unsightly and potentially unsafe to be placed in general-purpose office rooms.

In contrast, a plurality of specialized in-wall mounting apparatuses (705, 711, 717, 723) installed in various office rooms (701, 707, 713, 719) makes the distributed in-wall system configuration (700) feasible for implementation, maintenance, and coherent aesthetics. In the novel distributed in-wall system configuration (700) as shown in FIG. 7, the plurality of specialized in-wall mounting apparatuses (705, 711, 717, 723) are at least partially embedded or attached to vertical walls in multiple office rooms in lieu of a conventional main distribution frame (MDF) room. Some in-wall mounting apparatuses (705, 711, 717) may contain in-wall distributed PoE switches per room or per nearby locations, while other in-wall mounting apparatuses (723) may contain one or more virtualized hardware boxes that control and manage the in-wall distributed PoE switches, connected PoE devices, and/or other connected electronic devices (703, 709, 715, 721), such as localized data access points, wireless routers, Internet-of-Things (IoT) devices, and other components operatively connected to a corporate data network.

Furthermore, the distributed in-wall system configuration (700) is designed to connect the virtualized hardware box contained in one particular specialized in-wall mounting apparatus (723) with a plurality of in-wall distributed PoE switches contained by other specialized in-wall mounting apparatuses (705, 711, 717) in other rooms (i.e. 701, 707, 713) via in-wall distributed Ethernet cabling for PoE devices and/or in-wall fiber backbones, as shown in FIG. 7. The in-wall distributed Ethernet cabling and in-wall fiber backbones can improve the aesthetic appeal of an office environment, as each specialized in-wall mounting apparatus architecturally and visually “blends in” with existing office wall ornaments, hangable display panels, and other office electronic devices without openly exposing an unsightly clutter of Ethernet cables, power cords, and switches outside the specialized in-wall mounting apparatus that contains a virtualized hardware box, a PoE switch, and/or other data routing and transmission equipment.

Importantly, the distributed in-wall system configuration (700) can remove or reduce the need for the conventional MDF room, as data network and computer server equipment can be strategically and locally distributed to various office rooms and encapsulated by one or more in-wall mounting apparatuses (705, 711, 717, 723) in various office rooms. Furthermore, the distributed and in-wall-embedded nature of data network and computer server equipment optimizes office space management, while also reducing cable connection complexities and exorbitant power consumptions caused by the conventional MDF room. In some cases, the distributed in-wall system configuration (700) can also reduce backup generator power capacity requirements, as the total power consumption from distributed data network and computer server equipment is often less than the total power consumption required in the conventional MDF room.

Various embodiments of the present invention provide several advantages over horizontally-stacked conventional server racks and conventional MDF rooms in an office networking environment. One advantage of an embodiment of the present invention is providing a novel in-wall mounting apparatus that vertically and inversely orients, holds, and encapsulates a virtualized hardware box inside the apparatus. Another advantage of an embodiment of the present invention is incorporating a novel thermal dissipation meshed screen door into the in-wall mounting apparatus that provides effective passive cooling of virtualized hardware boxes and other electronic components contained by the specialized in-wall mounting apparatus.

Furthermore, another advantage of an embodiment of the present invention is providing a novel depth-axis-stackable (i.e. z-axis-stackable) installation of virtualized hardware boxes or other electronic equipment in the specialized in-wall mounting apparatus to achieve additional space efficiency relative to conventional horizontally-stacked server racks in an office environment. In addition, another advantage of an embodiment of the present invention is providing a distributed in-wall configuration of a plurality of virtualized hardware boxes and/or PoE switches contained in specialized in-wall mounting apparatuses in a multiple office room environment, which can replace a conventional main distribution frame (MDF) room or another centralized MDF location for higher space efficiency, reduced maintenance complexity, reduced equipment power consumption, and more pleasant office space aesthetics.

Moreover, another advantage of an embodiment of the present invention is providing a novel in-wall mounting apparatus that can be utilized in implementing a novel distributed in-wall configuration of multiple virtualized hardware boxes in a multiple office room environment to reduce IT equipment footprints in a space-constrained office environment, cable entanglements, misconnections, disconnections, and related troubleshooting needs.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the claims presented herein.

What is claimed is:

1. A specialized in-wall mounting apparatus comprising:
a main body frame configured to vertically and inversely orient and hold a virtualized hardware box inside the specialized in-wall mounting apparatus with one or more brackets, wherein a front plate of the virtualized hardware box faces down to be parallel to a floor and a rear plate of the virtualized hardware box faces up to keep a bottom surface and a top surface of the virtualized hardware box parallel to a vertical wall that attached the main body frame of the specialized in-wall mounting apparatus; and
an in-wall mount apparatus doorframe configured to open or close an enclosure space provided by the main body frame, wherein the in-wall mount apparatus doorframe opens outward from the vertical wall that attached the main body frame of the specialized in-wall mounting apparatus.

2. The specialized in-wall mounting apparatus of claim 1, further comprising a thermal dissipation meshed screen surrounded by the in-wall mount apparatus doorframe to form a thermal dissipation meshed screen front door that provides passive cooling to the virtualized hardware box vertically and inversely encapsulated by the specialized in-wall mounting apparatus.

3. The specialized in-wall mounting apparatus of claim 1, wherein the main body frame also provides a depth-axis or Z-axis stacking of additional virtualized hardware boxes in a depth-axis direction going into the vertical wall and behind the virtualized hardware box, or in another depth-axis direction going out of the vertical wall and in front of the virtualized hardware box, wherein the additional virtualized hardware boxes stacked in the depth axis or Z-axis are still fully enclosed by the main body frame of the specialized in-wall mounting apparatus.

4. The specialized in-wall mounting apparatus of claim 1, further comprising a door latch and a door lock integrated to the in-wall mount apparatus doorframe to deter theft and vandalism of the virtualized hardware box contained inside the specialized in-wall mounting apparatus.

5. The specialized in-wall mounting apparatus of claim 1, wherein the main body frame is docked into a carved-in section of the vertical wall for partial or full embedding into the vertical wall.

6. The specialized in-wall mounting apparatus of claim 1, wherein the virtualized hardware box inside the specialized in-wall mounting apparatus connects to power-over-Ethernet (PoE) switches and other electronic devices in another room via in-wall distributed Ethernet cabling or in-wall fiber backbones behind the vertical wall, without exposed cable or connection clutters commonly found in conventional server rack mounts.

7. The specialized in-wall mounting apparatus of claim 1, wherein the main body frame is also configured to contain at least one of a local data access point, a network router, a PoE device, and a fail-safe power supply unit.

8. The specialized in-wall mounting apparatus of claim 1, further comprising a glass or plastic window surrounded by the in-wall mount apparatus doorframe.

9. The specialized in-wall mounting apparatus of claim 1, wherein the virtualized hardware box encapsulated by the main body frame of the specialized in-wall mounting apparatus forms an innovative distributed in-wall system with another virtualized hardware box or a PoE switch encapsulated by a second specialized in-wall mounting apparatus in another room as a replacement of a centralized main distribution frame (MDF) room, wherein the specialized in-wall mounting apparatus and the second specialized in-wall mounting apparatus are connected by in-wall distributed Ethernet cabling or in-wall fiber backbones behind the vertical wall.

10. The specialized in-wall mounting apparatus of claim 1, wherein the front plate of the virtualized hardware box provides data connections and the rear plate of the virtualized hardware box provides power connections.
